(19) United States
(12) Patent Application Publication
(10) Pub. No.: US 2026/0238222 A1
(43) Pub. Date: Aug. 13, 2026

(54) A/D CONVERTER

(71) Applicant: Sony Semiconductor Solutions Corporation, Kanagawa (JP)

(72) Inventor: Eiichi NAKAMOTO, Kanagawa (JP)

(21) Appl. No.: 19/155,883

(22) PCT Filed: Jan. 9, 2024
(86) PCT No.: PCT/JP2024/000156

§ 371 Date: Aug. 12, 2025

(30) Foreign Application Priority Data
Mar. 2, 2023 (JP) 2023-032133

(51) Int. Cl. H03M 3/00

(52) U.S. Cl. CPC H03M 3/322; H03M 3/412; H03M 3/464

(57) ABSTRACT

Delay compensation of feedback of a delta-sigma AD converter is performed in a digital domain.

An AD converter includes an integration circuit that performs integration on the basis of an input signal and a first feedback signal fed back to the input signal, a first quantization circuit that performs first quantization on the basis of an output of the integration circuit, and a second quantization circuit that performs second quantization with accuracy coarser than the first quantization on the basis of an output of the first quantization circuit and a second feedback signal fed back to the output of the first quantization circuit. A DA converter that generates the first feedback signal on the basis of an output of the second quantization circuit may be further included.

### TECHNICAL FIELD

The present technology relates to an analog to digital (AD) converter. Specifically, the present technology relates to a continuous-time delta-sigma AD converter.

### BACKGROUND ART

A delta-sigma AD converter may be used in order to achieve high accuracy of AD conversion. Here, in the delta-sigma AD converter, there is a technology of performing DA conversion on a digital output and feeding back the digital output to an analog input in order to ensure conversion accuracy. For example, in order to compensate for delay of first feedback from an output side, a delta-sigma AD converter that applies second feedback from the output side at a timing earlier than the first feedback has been proposed (see, for example, Patent Document 1).

### CITATION LIST

### Patent Document

Patent Document 1: Japanese Patent Application Laid-Open No. 2010-239372

### SUMMARY OF THE INVENTION

### Problems to be Solved by the Invention

However, in the above-described related art, the second feedback that compensates for the delay of the first feedback is performed in an analog domain. Thus, a DA converter is separately required for the delay compensation, and there is a possibility of causing an increase in power consumption due to a DA conversion operation.

The present technology has been made in view of such a situation, and an object thereof is to perform delay compensation of feedback of a delta-sigma AD converter in a digital domain.

### Solutions to Problems

The present technology has been made to solve the above-described problem, and a first aspect thereof is an AD converter including an integration circuit that performs integration on the basis of an input signal and a first feedback signal fed back to the input signal, a first quantization circuit that performs first quantization on the basis of an output of the integration circuit, and a second quantization circuit that performs second quantization with accuracy coarser than the first quantization on the basis of an output of the first quantization circuit and a second feedback signal fed back to the output of the first quantization circuit. Therefore, an effect that the feedback of the delay compensation is performed in the digital domain while information of a quantized output is maintained is obtained.

Furthermore, in the first aspect, the second feedback signal may be a digital signal. Therefore, an effect that the digital signal is fed back to the quantized output is obtained.

Furthermore, in the first aspect, a digital to analog (DA) converter that generates the first feedback signal on the basis of an output of the second quantization circuit may be further included. Therefore, an effect that the digital output is DA-converted and fed back to the analog input is obtained.

Furthermore, in the first aspect, the DA converter may operate on the basis of a return to zero (RZ) method. Therefore, an effect that the pulse width of the pulse output from the DA converter is set for every sampling cycle is obtained.

Furthermore, in the first aspect, a step width of the first quantization circuit may be smaller than a step width of the DA converter. Therefore, an effect that feedback of the delay compensation is performed in the digital domain without the information of the quantized output is lost is obtained.

Furthermore, in the first aspect, a gain unit that generates the second feedback signal by multiplying an input of the second quantization circuit by a gain may be included. Therefore, an effect that a compensation amount of the delay of the feedback to the analog input is adjusted is obtained.

Furthermore, in the first aspect, the gain may be selected in accordance with accuracy of the first quantization circuit. Therefore, an effect that addition accuracy of a delay compensation amount in the digital domain is improved is obtained.

Furthermore, in the first aspect, the gain may be adjustable on the basis of a pulse width of a pulse output from the DA converter. Therefore, an effect that the delay compensation in the digital domain is realized while characteristics of a continuous-time filter that realizes an open-loop transfer function of the AD converter are maintained is obtained.

Furthermore, in the first aspect, the pulse width may be selected in accordance with the accuracy of the first quantization circuit. Therefore, an effect that accuracy of digital addition in delay compensation is improved is obtained.

Furthermore, in the first aspect, the gain may be adjustable on the basis of a delay time of a pulse output from the DA converter. Therefore, an effect that the delay compensation in the digital domain is realized while the characteristics of the continuous-time filter that realizes the open-loop transfer function of the AD converter are maintained is obtained.

Furthermore, in the first aspect, the gain may be set on the basis of a 0th-order term of an open-loop transfer function from an output to an input of the second quantization circuit. Therefore, an effect that feedback of delay compensation is completed in the digital domain is obtained.

Furthermore, in the first aspect, when a coefficient of a 1st-order integration when the open-loop transfer function is expressed by a 2nd-order transfer function is a₁, a coefficient of a 2nd-order integration is a₂, a delay time of a pulse output from the DA converter is α, and a pulse width of a pulse output from the DA converter is β−α, the gain k₀ is given by an expression of k₀=(1−β)/(β−α) (−a₁+a₂(1−α)/2). Therefore, an effect that delay compensation in the digital domain is achieved while Butterworth characteristics are imparted to the continuous-time filter that achieves the open-loop transfer function of the AD converter is obtained.

### BRIEF DESCRIPTION OF DRAWINGS

FIG. 1 is a block diagram illustrating a configuration example of an AD converter according to a first embodiment.

FIG. 2 is a timing chart illustrating an input and output example of a DA converter according to the first embodiment.

FIG. 3 is a block diagram illustrating a configuration example of a continuous-time filter that realizes an open-loop transfer function of an AD converter according to a second embodiment.

FIG. 4 is a timing chart illustrating a signal of each unit of the continuous-time filter according to the second embodiment.

### MODE FOR CARRYING OUT THE INVENTION

Modes for carrying out the present technology (hereinafter, referred to as embodiments) will be described below. The description will be given in the following order.
1. First embodiment (example in which quantization in two stages of high accuracy and low accuracy is performed such that feedback of delay compensation can be performed in a digital domain)
2. Second embodiment (example in which a gain of feedback of delay compensation performed in a digital domain is set on the basis of a 0th-order term when an open-loop transfer function from an output to an input of a quantization circuit is represented by a 2nd-order transfer function)

### 1. First Embodiment

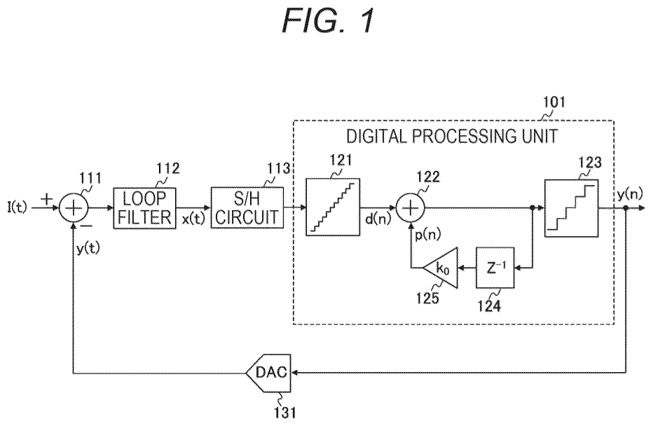

FIG. 1 is a block diagram illustrating a configuration example of an AD converter according to a first embodiment.

In the drawing, this AD converter operates as a continuous-time delta-sigma AD converter. The delta-sigma AD converter performs oversampling to reduce quantization noise. At this time, a change rate of a digital output of the delta-sigma AD converter from a low level to a high level depends on a change rate of an analog input. The continuous-time delta-sigma AD converter equivalently implements a discrete-time transfer function by using a continuous-time filter.

The AD converter performs DA conversion on a quantized output and feeds back the converted output to an analog input. Furthermore, the AD converter feeds back a quantized digital signal with higher accuracy than DA conversion accuracy to a quantized output in order to compensate for a delay of the feedback to an analog input.

The AD converter includes a subtraction circuit 111, a loop filter 112, a sample and hold circuit 113, a digital processing unit 101, and a DA converter 131. The digital processing unit 101 includes quantization circuits 121 and 123, an addition circuit 122, a delay circuit 124, and a gain unit 125. The digital processing unit 101 can perform processing in the digital domain.

The loop filter 112 is connected to a subsequent stage of the subtraction circuit 111, the sample and hold circuit 113 is connected to a subsequent stage of the loop filter 112, and the quantization circuit 121 is connected to a subsequent stage of the sample and hold circuit 113. The addition circuit 122 is connected to a subsequent stage of the quantization circuit 121, and the quantization circuit 123 is connected to a subsequent stage of the addition circuit 122.

Furthermore, an output of the quantization circuit 123 is connected to an input of the DA converter 131, and an output of the DA converter 131 is connected to a subtraction input of the subtraction circuit 111. An output of the addition circuit 122 is connected to an input of the delay circuit 124, an output of the delay circuit 124 is connected to an input of the gain unit 125, and an output of the gain unit 125 is connected to an input of the addition circuit 122.

The subtraction circuit 111 subtracts a feedback signal fed back to an analog input I(t) from an analog input I(t). An output y(t) of the DA converter 131 can be used as the feedback signal fed back to the analog input I(t). Note that (t) represents an analog signal.

The loop filter 112 integrates the output of the subtraction circuit 111 in the analog domain, and outputs an integrated value x(t) to the sample and hold circuit 113. At this time, the loop filter 112 determines transfer functions of noise and a signal. Here, the entire circuit can perform noise shaping by operating as a low-pass filter for signal input and operating as a high-pass filter for quantization noise. At this time, the loop filter 112 can suppress the quantization noise at a low frequency in a band of the signal and increase the quantization noise at a high frequency outside the band of the signal. Here, in the delta-sigma AD converter, the quantization noise is moved to a high frequency band by oversampling, and an S/N ratio by the noise shaping can be improved. The loop filter 112 can be implemented by connecting a plurality of integrators in series. Note that the loop filter 112 is an example of an integration circuit described in the claims.

The sample and hold circuit 113 samples and holds the integrated value x(t) output from the loop filter 112 and outputs the sampled and held integrated value to the quantization circuit 121.

The quantization circuit 121 quantizes the integrated value x(t) sampled and held by the sample and hold circuit 113 and outputs the quantized value to the addition circuit 122. A step width of the quantization circuit 121 can be smaller than a step width of the DA converter 131.

The addition circuit 122 adds a quantized output d(n) of the quantization circuit 121 and an output p(n) of the gain unit 125 and outputs the added value to the quantization circuit 123. Note that (n) represents a digital signal.

The quantization circuit 123 quantizes an output of the addition circuit 122. A quantized output y(n) of the quantization circuit 123 is used as an output of the delta-sigma AD converter and is also used as an input of the DA converter 131. The accuracy of the quantization circuit 123 can be made coarser than the accuracy of the quantization circuit 121.

The delay circuit 124 delays an input of the quantization circuit 123 by one sampling period and outputs the delayed value to the gain unit 125.

The gain unit 125 multiplies an input of the quantization circuit 123 delayed by the delay circuit 124 by a gain k₀ and outputs the multiplied value to the addition circuit 122. Here, the gain unit 125 can generate a feedback signal fed back to the quantized output d(n) of the quantization circuit 121 in the digital domain. For example, the gain k₀ may be set on the basis of a 0-th order term of an open-loop transfer function from the output to the input of the quantization circuit 123. At this time, the gain k₀ can be set to a decimal smaller than 1. Furthermore, the gain k₀ may be selected in accordance with the accuracy of the quantization circuit 121. At this time, the gain k₀ can be set such that digital addition corresponding to the accuracy of the quantization circuit 121 can be performed. For example, the gain k₀ may be selected from values such as 0.25, 0.5, and 0.75. For example, when the gain k₀=0.25, as long as the quantization circuit 121 has 4 times the accuracy of the DA converter 131, it is possible to accurately realize the digital addition after the quantization.

The DA converter 131 DA-converts the quantized output y(n) of the quantization circuit 123 and outputs the converted value to the subtraction input of the subtraction circuit 111. At this time, the DA converter 131 can operate on the basis of a return to zero (RZ) method.

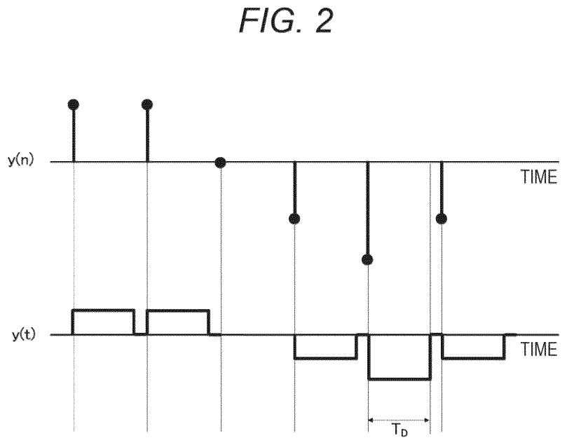

FIG. 2 is a timing chart illustrating an input and output example of the DA converter according to the first embodiment.

In the drawing, the DA converter 131 DA-converts the quantized output y(n) of the quantization circuit 123 to generate a pulsed output y(t). At this time, the DA converter 131 sets the output y(t) to 0 for every sampling period after the pulse output. At this time, the gain k₀ is adjustable on the basis of a pulse width T_{D} of a pulse output from the DA converter 131. Here, the gain k₀ is adjusted on the basis of the pulse width T_{D} of the pulse output from the DA converter 131, and thus, feedback of delay compensation can be performed in the digital domain while maintaining characteristics of the loop filter 112.

As described above, in the first embodiment described above, the quantization circuits 121 and 123 capable of performing quantization in two stages of high accuracy and low accuracy are provided, and feedback is performed between the quantization circuits 121 and 123. Therefore, the feedback of the delay compensation can be performed in the digital domain, and the DA converter used for the delay compensation can be unnecessary.

Furthermore, the accuracy of the quantization circuit 121 is set to be finer than the accuracy of the quantization circuit 123. Therefore, the gain k₀ can be selected in accordance with the accuracy of the quantization circuit 121 while setting the gain k₀ to a decimal number smaller than 1. Thus, the feedback of the delay compensation can be completed in the digital domain without losing information of the quantized output.

Furthermore, as for the gain k₀, the gain k₀ is set on the basis of the 0-th order term of the open-loop transfer function from the output to the input of the quantization circuit 123. Therefore, the feedback of the delay compensation can be performed.

Furthermore, the DA converter 131 operates on the basis of the RZ method. Therefore, the gain k₀ can be adjusted on the basis of the pulse width T_{D} of the pulse output from the DA converter 131 while suppressing interference between the outputs y(t) for every sampling period.

### 2. Second Embodiment

In the first embodiment described above, quantization is performed in two stages of high accuracy and low accuracy such that the feedback of the delay compensation can be performed in the digital domain. In a second embodiment, the gain k₀ is set on the basis of the 0th-order term when the open-loop transfer function from the output to the input of the quantization circuit 123 is expressed by a 2nd-order transfer function.

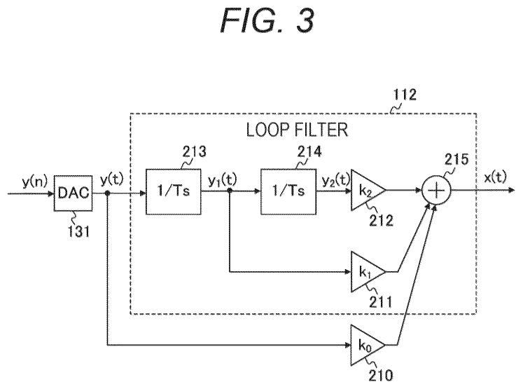

FIG. 3 is a block diagram illustrating a configuration example of a continuous-time filter that realizes an open-loop transfer function of an AD converter according to the second embodiment.

In the drawing, the continuous-time filter includes a DA converter 131, a loop filter 112, and a gain unit 210. The loop filter 112 includes integrators 213 and 214, gain units 211 and 212, and an adder 215.

The integrator 213 is connected to a subsequent stage of the DA converter 131, and the integrator 214 is connected to a subsequent stage of the integrator 213. Furthermore, an output y(t) of the DA converter 131 is input to the adder 215 via the gain unit 210, an output y₁(t) of the integrator 213 is input to the adder 215 via the gain unit 211, and an output y₂(t) of the integrator 214 is input to the adder 215 via the gain unit 212.

The transfer function of each integrator 213 or 214 can be expressed as 1/Ts. Note that s is a complex number, and T is a sampling cycle. The gain unit 210 multiplies the output y(t) of the DA converter 131 by the gain k₀ and outputs the multiplied value to the adder 215. The gain unit 211 multiplies the output y₁(t) of the integrator 213 by the gain k₁ and outputs the multiplied value to the adder 215. The gain unit 212 multiplies the output y₂(t) of the integrator 214 by the gain k₂ and outputs the multiplied value to the adder 215.

This continuous-time filter can convert the following 2nd-order discrete transfer function U(z) into a continuous-time circuit.

$$U ( z ) = {a}_{1} {z}^{- 1} / ( 1 - {z}^{- 1} ) + {a}_{2} {z}^{- 2} / {( 1 - {z}^{- 1} )}^{2} \qquad ( 1 )$$

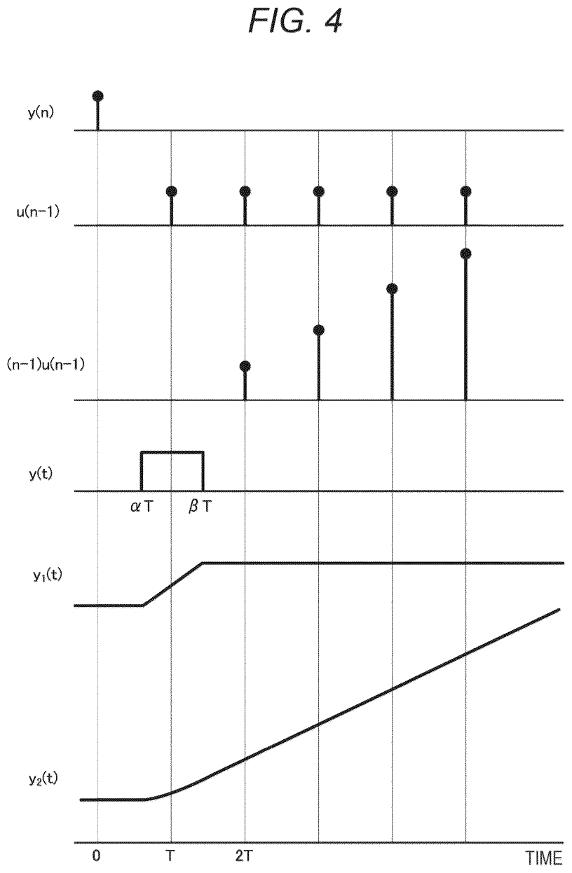

FIG. 4 is a timing chart illustrating a signal of each unit of the continuous-time filter according to the second embodiment.

In the drawing, an output x(t) of the continuous-time filter of FIG. 3 is sampled and quantized at the sampling cycle T, and the quantized output y(n) is fed back to the DA converter 131. At this time, the output y(t) of the DA converter 131 rises at time αT delayed from the quantized output y(n) and falls at time βT. Here, the pulse width T_{D} of the pulse which is the output y(t) of the DA converter 131 is given by β−α. At this time, the gain k₀ may be set on the basis of α or may be set on the basis of β−α.

Here, when the gains k₀ to k₂ are set by the following expressions, a continuous-time circuit equivalent to the discrete transfer function U(z) can be obtained for any a₁, a₂, α, and β.

$${k}_{0} = ( 1 - β ) / ( β - α ) ( - {a}_{1} + {a}_{2} ( 1 - α ) / 2 )$$

$${k}_{1} = 1 / ( β - α ) ( ( 2 {a}_{1} + {a}_{2} ( - 2 + β + α ) ) / 2 )$$

$${k}_{2} = {a}_{2} / ( β - α )$$

Here, in a case where the gain k₀ is adjusted, when a₁ and a₂ are changed, characteristics of the transfer function are affected. Thus, in a case where the gain k₀ is adjusted without changing the characteristics of the transfer function, it is desirable to change α and β.

Since the quantized output y(n) is a discrete signal, the DA converter 131 obtains a continuous-time output by 0th-order hold. Since the transfer function to be converted varies depending on a delay of the DA converter 131 and a length of the 0th-order hold, the transfer function is defined by α and β as illustrated in FIG. 4.

For example, in a case where the continuous-time filter has Butterworth characteristics, a₁=0.6713 and a₂=0.1744 are obtained. In a case where α=0.5 and β=1.5, k₀=0.31385 is obtained, and analog addition is necessary. On the other hand, when β=1.33 is set, since k₀ is a number close to 0.25(¼), a quantizer having 4 times the accuracy of the DA converter 131 can accurately realize digital addition even after quantization.

Hereinafter, an example of a method for calculating the gain k₀ will be described.

A transfer function H(s) of the continuous-time filter in FIG. 3 can be given by the following Expression (2).

$$H ( s ) = {k}_{0} + {k}_{1} / Ts + {k}_{2} / {T}^{2} {s}^{2} \qquad ( 2 )$$

The transfer function H(s) can indicate the open-loop transfer function from the output to the input of the quantization circuit 123 of FIG. 1.

Here, the output y(t) of the DA converter 131 has a pulse shape rising at time αT and falling at time RT. Thus, the output y₁(t) of the integrator 213 linearly increases during a pulse (from αT to βT) and becomes constant after a pulse (βT to). The output y₂(t) of the integrator 214 increases along a quadratic curve during the pulse (αT to βT) and increases linearly after a pulse (after βT).

Here, an impulse response of the continuous-time filter of FIG. 3 is considered. Since the output of the DA converter 131 is in a pulse shape having a width, it is considered separately for a response during the pulse (from αT to βT) and a response after the pulse (after PT). The response during the pulse (from αT to βT) can be given by the following Expression (3), and the response after the pulse (after βT) can be given by the following Expression (4).

$$α < t / T < β : x ( t ) = {k}_{0} + {k}_{1} ( t / T - α ) + {k}_{2} / 2 {( t / T - α )}^{2} \qquad ( 3 )$$

$$β < t / T : x ( t ) = {k}_{1} ( β - α ) + {k}_{2} ( {( β - α )}^{2} / 2 + ( β - α ) ( t / T - β ) ) \qquad ( 4 )$$

An impulse response of a 1st-order integral in Expression (1) can be given by an expression of u(n−1). In the response after the pulse (after βT) in Expression (4), since a slope of the output y₁(t) of the integrator 213 is 0, k₂=0 is obtained. Furthermore, in the response after the pulse (after βT) in Expression (4), when 1 is set after 2T, k₁(β−α)=1 is obtained, and a value of k₁=1/(β−α) is obtained.

In the response during the pulse (from αT to βT) in Expression (3), k₁ and k₂ obtained in the response after the pulse (after βT) are substituted and set to 1. At this time, k₀+k₁(t/T−α)=1 is obtained, and a value of k₀=(β−1)/(β−α) is obtained.

Accordingly, a transfer function H₁(s) of the continuous-time filter that converts the 1st-order integral in Expression (1) into continuous time can be given by the following Expression (5).

$${H}_{1} ( s ) = ( β - 1 + 1 / Ts ) / ( β - α ) \qquad ( 5 )$$

An impulse response of a 2nd-order integral in Expression (1) can be given by an expression of (n−1)·u(n−1). In the response after the pulse (after βT) in Expression (4), the following expression (6) can be obtained by differentiating in order to obtain the slope.

$$d / dt ( x ( t ) ) = {k}_{2} ( β - α ) / T \qquad ( 6 )$$

In Expression (6), when the slope is set to 1/T, a value of k₂=1/(β−α) is obtained. Furthermore, in Expression (6), when 1 is set at time 2T, k₁(β−α)+(β−α)/2+2−β=1 is obtained, and a value of k₁=(−2+β+α)/(2(β−α)) is obtained.

In the response during the pulse (from αT to βT) in Expression (4), k₁ and k₂ obtained in the response after the pulse (after βT) are substituted and set to 0. At this time, k₀+(−2+β+α)/(2(β−α))(1−α)+(1−α)²/(2(β−α))=0, and a value of k₀=(1−β)(1−α)/(2(β−α)) is obtained.

Accordingly, a transfer function H₂(s) of the continuous-time filter that converts a 2nd-order integral of Expression (1) into continuous time can be given by the following Expression (7).

$${H}_{2} ( s ) = ( ( 1 - β ) ( 1 - α ) / 2 ) + ( - 2 + β + α ) / ( 2 Ts ) + 1 / ( {T}^{2} {s}^{2} ) ) / ( β - α ) \qquad ( 7 )$$

Accordingly, the transfer function H(s) of the continuous-time filter in FIG. 3 can be given by the following Expression (8) from Expressions (5) and (7).

$$H ( s ) = {a}_{1} {H}_{1} ( s ) + {a}_{2} {H}_{2} ( s ) = ( - {a}_{1} + {a}_{2} ( 1 - α ) / 2 ) ( 1 - β ) + 2 {a}_{1} + {a}_{2} ( - 2 + β + α ) / 2 + {a}_{2} / ( {T}^{2} {s}^{2} ) ) ( β - α ) \qquad ( 8 )$$

As described above, in the second embodiment described above, the gain k₀ is set on the basis of the 0th-order term when the open-loop transfer function from the output to the input of the quantization circuit 123 is expressed by the 2nd-order transfer function. Therefore, it is possible to realize the delay compensation in the digital domain while imparting Butterworth characteristics to the continuous-time filter that realizes the open-loop transfer function of the AD converter.

Note that the embodiments described above indicate examples for embodying the present technology, and the matters in the embodiments and the matters specifying the invention in the claims have correspondence relationships. Similarly, the matters specifying the invention in the claims and the matters with the same names in the embodiments of the present technology have correspondence relationships. The present technology, however, is not limited to the embodiments, and can be embodied by making various modifications to the embodiments without departing from the scope of the present technology. Furthermore, the effects described in the present specification are merely examples and not limited, and other effects may be provided.

Note that the present technology can also have the following configurations.
(1) An AD converter including
an integration circuit that performs integration on the basis of an input signal and a first feedback signal fed back to the input signal,
a first quantization circuit that performs first quantization on the basis of an output of the integration circuit, and
a second quantization circuit that performs second quantization with accuracy coarser than the first quantization on the basis of an output of the first quantization circuit and a second feedback signal fed back to the output of the first quantization circuit.
(2) The AD converter according to the above (1), in which
the second feedback signal is a digital signal.
(3) The AD converter according to the above (1) or (2), further including
a digital to analog (DA) converter that generates the first feedback signal on the basis of an output of the second quantization circuit.
(4) The AD converter according to the above (3), in which
the DA converter operates on the basis of a return to zero (RZ) method.
(5) The AD converter according to the above (3) or (4), in which
a step width of the first quantization circuit is smaller than a step width of the DA converter.
(6) The AD converter according to any one of the above (3) to (5), further including
a gain unit that generates the second feedback signal by multiplying an input of the second quantization circuit by a gain.
(7) The AD converter according to the above (6), in which
the gain is selected in accordance with the accuracy of the first quantization circuit.
(8) The AD converter according to the above (6) or (7), in which
the gain is adjustable on the basis of a pulse width of a pulse output from the DA converter.
(9) The AD converter according to the above (8), in which
the pulse width is selected in accordance with the accuracy of the first quantization circuit.
(10) The AD converter according to any one of the above (6) to (9), in which
the gain is adjustable on the basis of a delay time of a pulse output from the DA converter.
(11) The AD converter according to any one of the above (6) to (10), in which
the gain is set on the basis of a 0th-order term of an open-loop transfer function from an output to an input of the second quantization circuit.
(12) The AD converter according to the above (11), in which,
when a coefficient of a 1st-order integration when the open-loop transfer function is expressed by a 2nd-order transfer function is a₁, a coefficient of a 2nd-order integration is a₂, a delay time of a pulse output from the DA converter is α, and a pulse width of a pulse output from the DA converter is β−α,
the gain k₀ is given by an expression of

$${k}_{0} = ( 1 - β ) / ( β - α ) ( - {a}_{1} + {a}_{2} ( 1 - α ) / 2 ) .$$

### REFERENCE SIGNS LIST

101 Digital processing unit
111 Subtraction circuit
112 Loop filter
113 Sample and hold circuit
121, 123 Quantization circuit
122 Addition circuit
124 Delay circuit
125 Gain unit
131 DA converter

1. An AD converter comprising:
an integration circuit that performs integration on a basis of an input signal and a first feedback signal fed back to the input signal;
a first quantization circuit that performs first quantization on a basis of an output of the integration circuit; and
a second quantization circuit that performs second quantization with accuracy coarser than the first quantization on a basis of an output of the first quantization circuit and a second feedback signal fed back to the output of the first quantization circuit.

2. The AD converter according to claim 1, wherein
the second feedback signal is a digital signal.

3. The AD converter according to claim 1, further comprising:
a digital to analog (DA) converter that generates the first feedback signal on a basis of an output of the second quantization circuit.

4. The AD converter according to claim 3, wherein
the DA converter operates on a basis of a return to zero (RZ) method.

5. The AD converter according to claim 3, wherein
a step width of the first quantization circuit is smaller than a step width of the DA converter.

6. The AD converter according to claim 3, further comprising:
a gain unit that generates the second feedback signal by multiplying an input of the second quantization circuit by a gain.

7. The AD converter according to claim 6, wherein
the gain is selected in accordance with the accuracy of the first quantization circuit.

8. The AD converter according to claim 6, wherein
the gain is adjustable on a basis of a pulse width of a pulse output from the DA converter.

9. The AD converter according to claim 8, wherein
the pulse width is selected in accordance with the accuracy of the first quantization circuit.

10. The AD converter according to claim 6, wherein
the gain is adjustable on a basis of a delay time of a pulse output from the DA converter.

11. The AD converter according to claim 6, wherein
the gain is set on a basis of a 0th-order term of an open-loop transfer function from an output to an input of the second quantization circuit.

12. The AD converter according to claim 11, wherein,
when a coefficient of a 1st-order integration when the open-loop transfer function is expressed by a 2nd-order transfer function is a₁, a coefficient of a 2nd-order integration is a₂, a delay time of a pulse output from the DA converter is α, and a pulse width of a pulse output from the DA converter is β−α,
the gain k₀ is given by an expression of
$${k}_{0} = ( 1 - β ) / ( β - α ) ( - {a}_{1} + {a}_{2} ( 1 - α ) / 2 ) .$$
